(19) United States
(12) Patent Application Publication
(10) Pub. No.: US 2008/0231273 A1
(43) Pub. Date: Sep. 25, 2008

(54) MAGNETIC RESONANCE IMAGING APPARATUS, MAGNETIC RESONANCE IMAGING METHOD AND SENSITIVITY DISTRIBUTION MEASURING APPARATUS

(76) Inventor: Hiroyuki Kabasawa, Tokyo (JP)

Correspondence Address: PATRICK W. RASCHE (20459);ARMSTRONG TEASDALE LLP, ONE METROPOLITAN SQUARE, SUITE 2600, ST. LOUIS, MO, 63102-2740, US

(21) Appl. No.: 12/051,908

(22) Filed: Mar. 20, 2008

(30) Foreign Application Priority Data
Mar. 23, 2007 (JP) 2007-077513

(51) Int. Cl. G01R 33/56

(52) U.S. Cl. 324/309

(57) ABSTRACT

A magnetic resonance imaging apparatus which executes a scan for allowing an RF coil unit to transmit RF pulses to an imaging area of a subject in a static magnetic filed space and allowing the RF coil unit to acquire magnetic resonance signals generated in the imaging area, includes: a scan section which executes, as the scan, each of an actual scan for acquiring the magnetic resonance signals as actual scan data and a reference scan for acquiring the magnetic resonance signals as reference scan data; an image reconstruction unit which reconstructs an actual scan image about the imaging area, based on the actual scan data and reconstructs a reference scan image about the imaging area, based on the reference scan data; a transmission sensitivity distribution calculating unit which calculates a transmission sensitivity distribution at the transmission of the RF pulses by the RF coil unit in the imaging area, based on the reference scan image and the actual scan image; and an image correcting unit which corrects the actual scan image using the transmission sensitivity distribution, wherein the transmission sensitivity distribution calculating unit includes: a division image generating part which executes image processing for dividing the first reference image by the second reference image, thereby generating a division image; a labeling information generating part which executes a labeling process on the division image thereby to generate labeling information about the division image; a segmentation process executing part which executes a segmentation process on the actual scan image, based on the labeling information thereby to extract a plurality of segments from the actual scan image; and a fitting processing part which calculates relational expressions indicative of relationships between pixel values of pixels constituting the segments and pixel positions thereof with respect to the segments extracted from the actual scan image, by performing a process for fitting to polynomial models, and wherein the transmission sensitivity distribution is calculated based on the relational expressions calculated by the fitting processing part.

### CROSS REFERENCE TO RELATED APPLICATIONS

This application claims the benefit of Japanese Patent Application No. 2007-077513 filed Mar. 23, 2007, which is hereby incorporated by reference in its entirety.

### BACKGROUND OF THE INVENTION

The field of the present invention relates to a magnetic resonance imaging apparatus, a magnetic resonance imaging method and a sensitivity distribution measuring apparatus. The present invention relates particularly to a magnetic resonance imaging apparatus, a magnetic resonance imaging method and a sensitivity distribution measuring apparatus each of which calculates a transmission sensitivity distribution at the transmission of each RF pulse to an imaging area by an RF coil unit.

A magnetic resonance imaging apparatus has been used in various fields such as a medical field, an industrial field, etc.

The magnetic resonance imaging apparatus includes an imaging space formed with a static magnetic field. An imaging area including a target for imaging at a subject is accommodated or held in the imaging space. Thus, spins of proton in the imaging area are arranged in the direction of the static magnetic field to obtain magnetization vectors thereof. Thereafter, each RF pulse is transmitted to the imaging area of the subject in the imaging space formed with the static magnetic field to generate a nuclear magnetic resonance (NMR) phenomenon, thereby flipping the magnetization vectors of the spins. Then, magnetic resonance (MR) signals generated when the flipped magnetization vectors of spins are returned in an original static magnetic-field direction, are acquired. The subject is scanned in accordance with, for example, a pulse sequence such as a spin echo (SE) system, a gradient recalled echo (GRE) system or the like. Then, image reconstruction processing is effected on magnetic resonance signals acquired by execution of this scan to generate slice images about an imaging area of the subject.

As an RF coil for receiving each magnetic resonance signal in the magnetic resonance imaging apparatus, a surface coil such as a phased array coil has frequently been used. However, the surface coil has the characteristic that sensitivity to be received is lowered as the distance to the source of generation of each magnetic resonance signal in the subject increases, and a sensitivity distribution in the entire imaging area is not uniform spatially. Therefore, there is a case where an image generated based on each magnetic resonance signal received by the surface coil will cause artifacts and hence image quality is degraded.

Therefore, a correcting process is performed on each image-reconstructed image using a reception sensitivity distribution in order to cope with problems or defective conditions caused by reception sensitivity ununiformity of such a surface coil. Described specifically, a reference image is reconstructed by executing a reference scan in addition to an actual scan, and a reception sensitivity distribution in the imaging area of the surface coil is measured using the reference image. Thereafter, an actual scan image generated by the actual scan is corrected using the measured reception sensitivity distribution (refer to, for example, Japanese Unexamined Patent Publication No. 2005-177240).

However, there is a case where upon imaging or photographing an imaging area of a subject, a high-frequency magnetic field formed by allowing an RF coil such as a body coil to transmit each RF pulse becomes ununiform in an imaging space due to a dielectric-constant effect. Therefore, there is a case in which even when the actual scan image is corrected using the above reception sensitivity distribution, the artifacts cannot be removed sufficiently. That is, there is a case where it is difficult to enhance the quality of the actual scan image due to a transmission sensitivity distribution being ununiform spatially.

Described specifically, there is a case in which a defective condition such as a reduction in image's contrast occurs. Such a defective condition occurs remarkably in an imaging space in which a high magnetic field whose intensity is three teslas or higher.

Thus, there have been proposed (1) a method of executing a reference scan in addition to an actual scan, thereafter measuring a transmission sensitivity distribution in a living body, based on a reference image reconstructed by execution of the reference scan and correcting an actual scan image using the measured transmission sensitivity distribution, (2) a method of measuring a transmission sensitivity distribution from a signal intensity distribution of an actual scan image itself and correcting the actual scan image using the measured transmission sensitivity distribution, and the like.

Measuring the transmission sensitivity distribution by, for example, a double flip angle method has been proposed as the method of the former (1). Described specifically, a plurality of reference scans are executed at flip angles different from one another and transmission sensitivity distributions are measured using reference images obtained by the respective reference scans. Thereafter, the actual scan image is corrected using each of the transmission sensitivity distributions, thereby preventing the occurrence of artifacts in the actual scan image (refer to, for example, Hiroaki Mihara, et. al, “A Method of RF Inhomogeneity Correction in MR Imaging,” Magnetic Resonance Materials in Physics, Biology and Medicine 7, USA, 1998, p 115-p 120 and Jinghua Wang, et. al., “In vivo Method for Correcting Transmit/Receive Nonuniformites with Phased Array Coils,” Magnetic Resonance in Medicine 53, USA, 2005, p 666-p 674).

There has been proposed a method of executing a plurality of reference scans in such a manner that a flip angle changes stepwise, reconstructing plural reference scan images so as to correspond to the plurality of reference scans, and thereafter calculating transmission sensitivity distributions, based on the plural reference scan images (refer to E. De Vita, et. al., “Fast B1 Mapping with EPI,” Magnetic Resonance in Medicine 11, USA, 2004, p. 2090).

Here, each rectangular RF pulse is increased stepwise by changing its applying time with constant amplitude without applying a slice selection gradient magnetic field at each of the plural reference scans. A spoiler gradient magnetic field is applied after the transmission of the RF pulse.

Thereafter, frequency spectrums are calculated by fast Fourier-transforming transition data of pixel values transitioned corresponding to the execution of the reference scans between the reconstructed plural reference scan images. Thereafter, transmission sensitivity distributions are calculated based on the calculated frequency spectrums. According to this method, the transmission sensitivity distributions can easily be measured with a high degree of accuracy and at high speed as compared with the double flip angle method.

On the other hand, as the method of the latter (2), there are known a method of estimating ununiformity using a sensitivity distribution model from actual scan image data, and a method of performing a histogram analysis thereby to estimate ununiformity (refer to, for example, M. Styner, et. al., “Parametric Estimate of Intensity In homogeneities Applied to MRI,” IEEE Trans. Med. Imag. 19, 3, 2000, p 153-165 and John G. Sled, et. al, “A Nonparametric Method for Automatic Correction of Intensity Nonuniformity in MRI Data,” IEEE, Trans. Med. Imag. 17, 1, 1998, p 87-97).

Since, however, the method of the former (1) may be affected by physical characteristics such as a longitudinal relaxation time T1 at a target to be imaged, its horizontal relaxation time T2 and the like, and body motion, it may be difficult to calculate the transmission sensitivity distribution with a high degree of accuracy. Since the theoretical formula is established in a pulse sequence of a general SE system or GRE system, it is easy to calculate the transmission sensitivity distribution from each reference image. It is, however, not easy to calculate a transmission sensitivity distribution from each reference image in a pulse sequence of an FSE (Fast Spin Echo) system, an SSFP (Steady State Free Precession) system.

Further, the method of the latter (2) is affected by a high-intensity signal portion and a low-intensity signal portion existing in the actual scan image, and hence contrast between tissues existing in the imaging area may be altered. It is therefore difficult to calculate the transmission sensitivity distribution with a high degree of accuracy.

Since it is not easy to calculate each transmission sensitivity distribution with a high degree of accuracy in this way, there was a case in which it was difficult to enhance the quality of the actual scan image.

### SUMMARY OF THE INVENTION

In a first aspect, there is provided a magnetic resonance imaging apparatus of the invention, which executes a scan for allowing an RF coil unit to transmit RF pulses to an imaging area of a subject in a static magnetic filed space and allowing the RF coil unit to acquire magnetic resonance signals generated in the imaging area, including: a scan section which executes, as the scan, each of an actual scan for acquiring the magnetic resonance signals as actual scan data and a reference scan for acquiring the magnetic resonance signals as reference scan data; an image reconstruction unit which reconstructs an actual scan image about the imaging area, based on the actual scan data and reconstructs a reference scan image about the imaging area, based on the reference scan data; a transmission sensitivity distribution calculating unit which generates a transmission sensitivity distribution at the transmission of the RF pulses by the RF coil unit in the imaging area, based on the reference scan image and the actual scan image; and an image correcting unit which corrects the actual scan image using the transmission sensitivity distribution, wherein the RF coil unit includes a first RF coil, and a second RF coil non-uniform in reception sensitivity distribution as compared with the first RF coil in the imaging area, wherein upon execution of the actual scan, the scan section transmits the RF pulses to the imaging area by the first RF coil and receives the magnetic resonance signals generated in the imaging area as the actual scan data by the second RF coil, and upon execution of the reference scan, the scan section executes a first reference scan for transmitting RF pulses to the imaging area by the first RF coil and receiving magnetic resonance signals generated in the imaging area as first reference scan data by the first RF coil, under a first reference scan condition corresponding to a pulse sequence of a spin echo system or a gradient echo system, and a second reference scan for transmitting RF pulses to the imaging area by the first RF coil and receiving magnetic resonance signals generated in the imaging area as second reference scan data by the first RF coil, under a second reference scan condition corresponding to the same pulse sequence as the first reference scan condition and different from the first reference scan condition in terms of at least one of other scan parameters, wherein the image reconstruction unit image-reconstructs a first reference image as the reference scan image, based on the first reference scan data and image-reconstructs a second reference image as the reference scan image, based on the second reference scan data, wherein the transmission sensitivity distribution calculating unit includes a division image generating part which executes image processing for dividing the first reference image by the second reference image, thereby generating a division image, a labeling information generating part which executes a labeling process on the division image thereby to generate labeling information about the division image, a segmentation process executing part which executes a segmentation process on the actual scan image, based on the labeling information thereby to extract a plurality of segments from the actual scan image, and a fitting processing part which calculates relational expressions indicative of relationships between pixel values of pixels constituting the segments and pixel positions thereof with respect to the segments extracted from the actual scan image, by performing a process for fitting to polynomial models, and wherein the transmission sensitivity distribution is calculated based on the relational expressions calculated by the fitting processing part.

Preferably, the magnetic resonance imaging apparatus includes a reception sensitivity distribution calculating unit which calculates a reception sensitivity distribution at the reception of the magnetic resonance signals by the RF coil unit in the imaging area, and the image correcting unit executes image processing for dividing the actual scan image by the reception sensitivity distribution thereby to correct the actual scan image.

Preferably, the segmentation process executing part executes image processing for dividing the actual scan image by the reception sensitivity distribution thereby to correct the actual scan image and thereafter executes the segmentation process on the post-correction actual scan image.

Preferably, the scan section executes, as the reference scan, a third reference scan for transmitting RF pulses to the imaging area by the first RF coil and receiving magnetic resonance signals generated in the imaging area as third reference scan data by the second RF coil, under the first reference scan condition, the image reconstruction unit image-reconstructs a third reference image as the reference scan image, based on the third reference scan data, and the reception sensitivity distribution calculating unit executes image processing for dividing the third reference image by the first reference image thereby to calculate the reception sensitivity distribution.

Preferably, the first RF coil is a body coil and the second RF coil is a surface coil.

Preferably, the magnetic resonance imaging apparatus includes a display unit that displays the actual scan image corrected by the image correcting unit.

In a second aspect, there is provided a magnetic resonance imaging method of the invention, which executes a scan for causing an RF coil unit including a first RF coil and a second RF coil ununiform in reception sensitivity distribution as compared with the first RF coil to transmit RF pulses to an imaging area of a subject in a static magnetic field space and causing the RF coil unit to acquire magnetic resonance signals generated in the imaging area, thereby generating images about the imaging area, including the steps: a scan step for executing, as the scan, each of an actual scan for acquiring the magnetic resonance signals as actual scan data and a reference scan for acquiring the magnetic resonance signals as reference scan data; an image reconstructing step for reconstructing an actual scan image about the imaging area, based on the actual scan data and reconstructing a reference scan image about the imaging area, based on the reference scan data; a transmission sensitivity distribution calculating step for generating a transmission sensitivity distribution at the transmission of the RF pulses by the RF coil unit in the imaging area, based on the reference scan image and the actual scan image; and an image correcting step for correcting the actual scan image using the transmission sensitivity distribution, wherein in the scan step, when the actual scan is executed, the first RF coil transmits RF pulses to the imaging area and the second RF coil receives magnetic resonance signals generated in the imaging area as the actual scan data, whereas when the reference scan is executed, a first reference scan for transmitting RF pulses to the imaging area by the first RF coil and receiving magnetic resonance signals generated in the imaging area as first reference scan data by the first RF coil, under a first reference scan condition corresponding to a pulse sequence of a spin echo system or a gradient echo system, and a second reference scan for transmitting RF pulses to the imaging area by the first RF coil and receiving magnetic resonance signals generated in the imaging area as second reference scan data by the first RF coil, under a second reference scan condition corresponding to the same pulse sequence as the first reference scan condition and different from the first reference scan condition in terms of at least one of other scan parameters are executed, wherein in the image reconstruction step, a first reference image is image-reconstructed as the reference scan image, based on the first reference scan data, and a second reference image is image-reconstructed as the reference scan image, based on the second reference scan data, wherein the transmission sensitivity distribution calculating step includes a division image generating step for executing image processing for dividing the first reference image by the second reference image thereby to generate a division image, a labeling information generating step for executing a labeling process on the division image thereby to generate labeling information about the division image, a segmentation process executing step for executing a segmentation process on the actual scan image, based on the labeling information thereby to extract a plurality of segments from the actual scan image, and a fitting processing step for calculating relational expressions indicative of relationships between pixel values of pixels constituting the segments and pixel positions thereof with respect to the segments extracted from the actual scan image, by performing a process for fitting to polynomial models, and wherein the transmission sensitivity distribution is calculated based on the relational expressions calculated by the fitting processing step.

Preferably, the magnetic resonance imaging method includes a reception sensitivity distribution calculating step for calculating a reception sensitivity distribution at the reception of the magnetic resonance signals by the RF coil unit in the imaging area. In the image correcting step, image processing for dividing the actual scan image by the reception sensitivity distribution is executed to correct the actual scan image.

Preferably, in the segmentation process executing step, image processing for dividing the actual scan image by the reception sensitivity distribution is executed to correct the actual scan image and thereafter, the segmentation process is performed on the post-correction actual scan image.

Preferably, in the scan step, a third reference scan for transmitting RF pulses to the imaging area by the first RF coil and receiving magnetic resonance signals generated in the imaging area as third reference scan data by the second RF coil, under the first reference scan condition is executed as the reference scan. In the image reconstruction step, a third reference image is image-reconstructed as the reference scan image, based on the third reference scan data. In the reception sensitivity distribution calculating step, image processing for dividing the third reference image by the first reference image is executed to calculate the reception sensitivity distribution.

Preferably, the first RF coil is a body coil and the second RF coil is a surface coil.

Preferably, the actual scan image corrected by the image correcting step is displayed.

In a third aspect, there is provided a sensitivity distribution measuring apparatus of the invention, which executes, as a scan for allowing an RF coil unit to transmit RF pulses to an imaging area of a subject in a static magnetic filed space and allowing the RF coil unit to acquire magnetic resonance signals generated in the imaging area, each of an actual scan for acquiring the magnetic resonance signals as actual scan data and a reference scan for acquiring the magnetic resonance signals as reference scan data, and thereafter calculates a transmission sensitivity distribution at the transmission of the RF pulses by the RF coil unit in the imaging area, based on the actual scan data and the reference scan data, the sensitivity distribution measuring apparatus including an image reconstruction unit which reconstructs an actual scan image about the imaging area, based on the actual scan data and reconstructs a reference scan image about the imaging area, based on the reference scan data; and a transmission sensitivity distribution calculating unit which generates a transmission sensitivity distribution at the transmission of the RF pulses by the RF coil unit in the imaging area, based on the reference scan image and the actual scan image, wherein the RF coil unit includes a first RF coil, and a second RF coil ununiform in reception sensitivity distribution as compared with the first RF coil in the imaging area, wherein upon execution of the actual scan, the first RF coil is caused to transmit the RF pulses to the imaging area, and the second RF coil is caused to receive the magnetic resonance signals generated in the imaging area as the actual scan data, wherein upon execution of the reference scan, a first reference scan for causing the first RF coil to transmit RF pulses to the imaging area and causing the first RF coil to receive magnetic resonance signals generated in the imaging area as first reference scan data, under a first reference scan condition corresponding to a pulse sequence of a spin echo system or a gradient echo system, and a second reference scan for causing the first RF coil to transmit RF pulses to the imaging area and causing the first RF coil to receive magnetic resonance signals generated in the imaging area as second reference scan data, under a second reference scan condition corresponding to the same pulse sequence as the first reference scan condition and different from the first reference scan condition in terms of at least one of other scan parameters are executed, wherein when the reference scan image is reconstructed, a first reference image is image-reconstructed based on the first reference scan data and a second reference image is image-reconstructed based on the second reference scan data, wherein the image reconstruction unit image-reconstructs the first reference image as the reference scan image, based on the first reference scan data, and image-reconstructs the second reference image as the reference scan image, based on the second reference scan data, wherein the transmission sensitivity distribution calculating unit includes a division image generating part which executes image processing for dividing the first reference image by the second reference image, thereby generating a division image, a labeling information generating part which executes a labeling process on the division image thereby to generate labeling information about the division image, a segmentation process executing part which executes a segmentation process on the actual scan image, based on the labeling information thereby to extract a plurality of segments from the actual scan image, and a fitting processing part which calculates relational expressions indicative of relationships between pixel values of pixels constituting the segments and pixel positions thereof with respect to the segments extracted from the actual scan image, by performing a process for fitting to polynomial models, and wherein the transmission sensitivity distribution is calculated based on the relational expressions calculated by the fitting processing part.

Preferably, the sensitivity distribution measuring apparatus includes a reception sensitivity distribution calculating unit which calculates a reception sensitivity distribution at the reception of the magnetic resonance signals by the RF coil unit in the imaging area, and the segmentation process executing part executes image processing for dividing the actual scan image by the reception sensitivity distribution thereby to correct the actual scan image and thereafter executes the segmentation process on the post-correction actual scan image.

Preferably, the scan section executes, as the reference scan, a third reference scan for transmitting RF pulses to the imaging area by the first RF coil and receiving magnetic resonance signals generated in the imaging area as third reference scan data by the second RF coil, the image reconstruction unit image-reconstructs a third reference image as the reference scan image, based on the third reference scan data, and the reception sensitivity distribution calculating unit executes image processing for dividing the third reference image by the first reference image thereby to calculate the reception sensitivity distribution.

Preferably, the first RF coil is a body coil and the second RF coil is a surface coil.

According to the invention, there can be provided a magnetic resonance imaging apparatus, a magnetic resonance imaging method and a sensitivity distribution measuring apparatus each of which is capable of measuring a transmission sensitivity distribution with a high degree of accuracy and enhancing image quality.

Further objects and advantages of the present invention will be apparent from the following description of the preferred embodiments of the invention as illustrated in the accompanying drawings.

### BRIEF DESCRIPTION OF THE DRAWINGS

FIG. 1 is a configuration diagram showing a construction of a magnetic resonance imaging apparatus 1 illustrative of an embodiment according to the invention.

FIG. 2 is a block diagram showing a data processor 31 employed in the embodiment according to the invention.

FIG. 3 is a flowchart showing operation taken when an imaging area of a subject SU is photographed in the embodiment according to the invention.

FIG. 4 is a diagram showing the flow of data at the photography of the imaging area of the subject SU.

FIG. 5 is a flowchart showing operation taken when a transmission sensitivity distribution T (x, y) is generated in the embodiment according to the invention.

FIG. 6 is a diagram showing the flow of data at the generation of the transmission sensitivity distribution T (x, y) in the embodiment according to the invention.

FIG. 7 is an explanatory diagram for conceptually describing operation taken when the transmission sensitivity distribution T (x, y) is generated in the embodiment according to the invention.

FIG. 8 is an explanatory diagram for conceptually describing operation taken when a transmission sensitivity distribution T (x, y) is generated in the embodiment according to the invention.

### DETAILED DESCRIPTION OF THE INVENTION

One example of an embodiment according to the invention will be explained below with reference to the accompanying drawings.

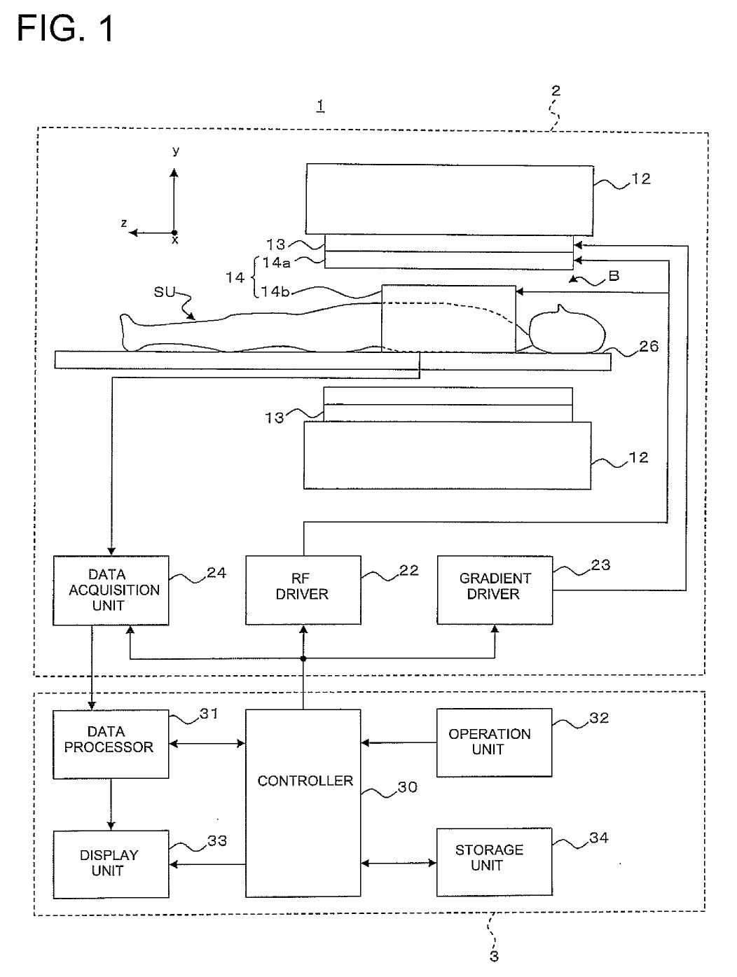

FIG. 1 is a configuration diagram showing the construction of a magnetic resonance imaging apparatus 1 illustrative of an embodiment according to the invention.

As shown in FIG. 1, the magnetic resonance imaging apparatus 1 has a scan section 2 and an operation console section 3.

Here, the scan section 2 has a static magnetic field magnet unit 12, a gradient coil unit 13, an RF coil unit or part 14, an RF driver 22, a gradient driver 23, a data acquisition unit 24 and a cradle 26 as shown in FIG. 1. As shown in FIG. 1, the operation console section 3 has a controller 30, a data processor 31, an operation unit 32, a display or display unit 33 and a storage unit 34.

As shown in FIG. 1, the scan section 2 includes an imaging space B which is formed with a static magnetic field and in which an imaging area containing a target for imaging at the subject SU is accommodated or held. The scan section 2 applies RF pulses to the imaging area of the subject SU accommodated in the imaging space B formed with the static magnetic field, based on a control signal outputted from the operation console section 3 to acquire magnetic resonance signals produced from the imaging area, thereby executing a scan for the imaging area of the subject SU.

In the present embodiment, the scan section 2 executes an actual scan for acquiring the magnetic resonance signals as actual scan data, and a reference scan for acquiring the magnetic resonance signals as reference scan data, as scans respectively.

Although the details of the scan section 2 will be described later, as shown in FIG. 1 here, the RF coil unit 14 includes a first RF coil 14a, and a second RF coil 14b ununiform in reception sensitivity distribution as compared with the first RF coil 14a in the imaging area. The scan section 2 causes the first RF coil 14a to transmit RF pulses to the imaging area upon execution of the actual scan and causes the second RF coil 14b to receive magnetic resonance signals generated in the imaging area as actual scan data. Upon execution of the reference scan, the scan section 2 executes a first reference scan for transmitting RF pulses to the imaging area by the first RF coil 14a and receiving magnetic resonance signals generated in the imaging area as first reference scan data by the first RF coil 14a, under a first reference scan condition corresponding to a pulse sequence of a spin echo system or a gradient echo system, and a second reference scan for transmitting RF pulses to the imaging area by the first RF coil 14a and receiving magnetic resonance signals generated in the imaging area as second reference scan data by the first RF coil 14a, under a second reference scan condition corresponding to the same pulse sequence as the first reference scan condition and different from the first reference scan condition in terms of at least one of other scan parameters. In addition to the above, the scan section 2 executes, as the reference scan, a third reference scan for transmitting RF pulses to the imaging area by the first RF coil 14a and receiving magnetic resonance signals generated in the imaging area as third reference scan data by the second RF coil 14b, under the first reference scan condition.

The static magnetic field magnet unit 12 is constituted of, for example, a superconductive magnet (not shown). The superconductive magnet forms a static magnetic field in the imaging space B in which the subject SU is accommodated or held. Here, the static magnetic field magnet unit 12 forms a static magnetic field along the horizontal direction in which the cradle 26 with the subject placed thereon is moved. That is, the static magnetic filed magnet unit 12 forms the static magnetic field along the direction (z direction) of a body axis of the subject SU. Incidentally, the static magnetic field magnet unit 12 may be constituted of a pair of permanent magnets.

The gradient coil unit 13 forms a gradient magnetic field by transmitting each gradient pulse to the imaging space B formed with the static magnetic field and applies or adds spatial position information to each magnetic resonance signal received by the RF coil unit 14. Here, the gradient coil unit 13 includes three systems set so as to correspond to three-axis directions of a z direction extending along a static magnetic field direction, an x direction and a y direction orthogonal to one another. These transmit gradient pulses in a frequency encode direction, a phase encode direction and a slice selection direction so as to form gradient magnetic fields according to imaging conditions. Described specifically, the gradient coil unit 13 applies the gradient magnetic field in the slice selection direction of the subject SU and selects each slice of the subject SU excited by transmission of an RF pulse by the RF coil unit 14. The gradient coil unit 13 applies the gradient magnetic field in the phase encode direction of the subject SU and phase-encodes a magnetic resonance signal from the slice excited by the RF pulse. And the gradient coil unit 13 applies the gradient magnetic field in the frequency encode direction of the subject SU and frequency-encodes the magnetic resonance signal from the slice excited by the RF pulse.

The RF coil unit 14 transmits an RF pulse corresponding to an electromagnetic wave to the imaging area of the subject SU within the imaging space B formed with the static magnetic field by the static magnetic field magnet unit 12 thereby to form a high frequency magnetic field. Thus, magnetization vectors based on the spins of proton in the imaging area of the subject SU are flipped. Further, the RF coil unit 14 receives an electromagnetic wave generated when each flipped magnetization vector is returned to the original magnetization vector extending along the static magnetic field direction, as a magnetic resonance signal.

In the present embodiment, the RF coil unit 14 has a first RF coil 14a and a second RF coil 14b as shown in FIG. 1. Here, the first RF coil 14a is of, for example, a birdcage type body coil, which is disposed so as to surround the imaging area of the subject SU. This executes the transmission and reception of each RF pulse, for example. On the other hand, the second RF coil 14b is of a surface coil, which executes the reception of each magnetic resonance signal, for example.

The RF driver 22 drives the RF coil unit 14 to transmit an RF pulse to within the imaging space B, thereby forming a high frequency magnetic field in the imaging space B. The RF driver 22 modulates a signal sent from an RF oscillator (not shown) to a signal having predetermined timing and predetermined envelope using a gate modulator (not shown) on the basis of a control signal outputted from the controller 30. Thereafter, the RF driver 22 allows an RF power amplifier to amplify the signal modulated by the gate modulator and outputs the same to the RF coil unit 14, and allows the RF coil unit 14 to transmit the corresponding RF pulse.

The gradient driver 23 drives the gradient coil unit 13 to transmit a gradient pulse, based on the control signal outputted from the controller 30 thereby to generate a gradient magnetic field within the imaging space B formed with the static magnetic field. The gradient driver 23 has a three-system drive circuit (not shown) in association with the three-system gradient coil unit 13.

The data acquisition unit 24 acquires each magnetic resonance signal received by the RF coil unit 14 based on the control signal outputted from the controller 30. Here, the data acquisition unit 24 phase-detects the magnetic resonance signal received by the RF coil unit 14, using a phase detector (not shown) with the output of the RF oscillator (not shown) of the RF driver 22 as a reference signal. Thereafter, an A/D converter (not shown) converts the magnetic resonance signal corresponding to the analog signal into a digital signal and outputs it therefrom.

The cradle 26 has a table including a horizontal plane, which places the subject SU thereon. A drive motor is driven based on the corresponding control signal outputted from the controller 30 to move the table between the inside and outside of the imaging space B.

As shown in FIG. 1, the operation console section 3 has the controller 30, the data processor 31, the operation unit 32, the display or display unit 33 and the storage unit 34.

The controller 30 has a computer and a memory that stores programs that allow the computer to execute predetermined data processing, and controls respective parts. Here, the controller 30 inputs operation data sent from the operation unit 32 and outputs control signals to the RF driver 22, gradient driver 23, data acquisition unit 24 and cradle 26 based on the operation data inputted from the operation unit 32 thereby to execute a predetermined scan. Along with it, the controller 30 outputs control signals to the data processor 31, display unit 33 and storage unit 34 to perform control thereof.

The data processor 31 has a computer and a memory that stores therein programs for executing predetermined data processing using the computer. The data processor 31 executes data processing, based on the control signal supplied from the controller 30. Here, the data processor 31 uses each magnetic resonance signal acquired by executing the scan by means of the scan section 2 as raw data and thereby generates images about the imaging area of the subject SU. And the data processor 31 outputs each generated image to the display unit 33.

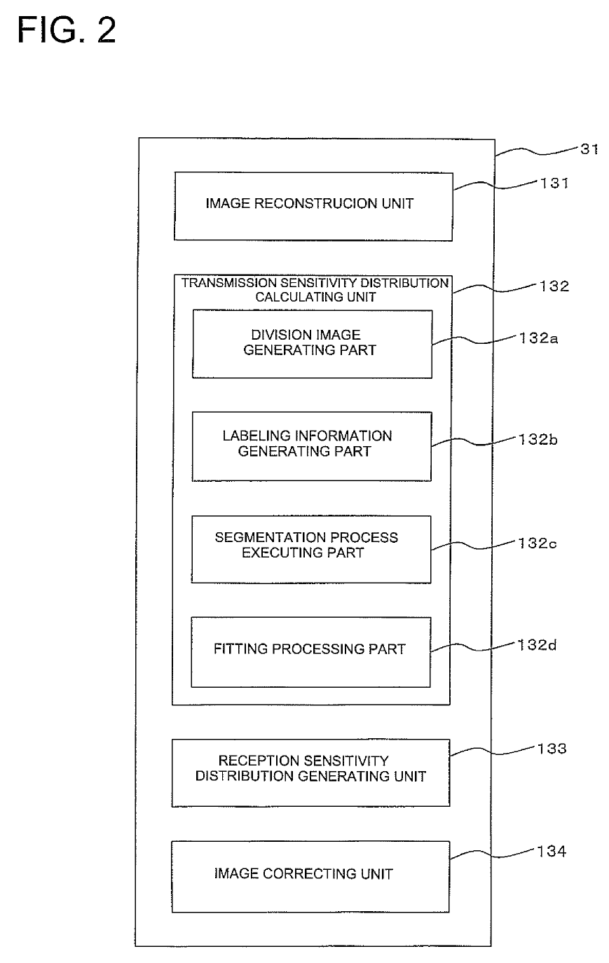

FIG. 2 is a block diagram showing the data processor 31 in the embodiment according to the invention.

As shown in FIG. 2, the data processor 31 has an image reconstruction unit 131, a transmission sensitivity distribution calculating unit 132, a reception sensitivity distribution calculating unit 133 and an image correcting unit 134.

Here, the image reconstruction unit 131 uses each magnetic resonance signal obtained as actual scan data by executing the actual scan about the imaging area of the subject SU, as raw data, thereby image-reconstructing an actual scan image about the imaging area of the subject SU. That is, the actual scan image is image-reconstructed based on the actual scan data by, upon execution of the actual scan by the scan section 2, transmitting the RF pulses to the imaging area by means of the first RF coil 14a and receiving the magnetic resonance signals produced in the imaging area by means of the second RF coil 14b.

The image reconstruction unit 131 uses each magnetic resonance signal obtained as reference scan data by the reference scan executed before the execution of the actual scan about the imaging area of the subject SU, as raw data, thereby image-reconstructing a reference scan image about the imaging area of the subject SU.

In the present embodiment, the image reconstruction unit 131 image-reconstructs a first reference image, based on first reference scan data as the present reference scan image. That is, when the scan section 2 executes a first reference scan as a reference scan, a first reference image is image-reconstructed under a first reference scan condition corresponding to a spin echo or gradient echo pulse sequence on the basis of first reference scan data acquired by transmitting RF pulses to the imaging area by means of the first RF coil 14a and receiving magnetic resonance signals generated in the imaging area by means of the first RF coil 14a.

The image reconstruction unit 131 image-reconstructs a second reference image, based on second reference scan data as a reference scan image. That is, when the scan section 2 executes a second reference scan as a reference scan, a second reference image is image-reconstructed under a second reference scan condition which corresponds to the same pulse sequence as the first reference scan condition and in which at least one of other scan parameters is different from the first reference scan condition, on the basis of second reference scan data acquired by transmitting RF pulses to the imaging area by means of the first RF coil 14a and receiving magnetic resonance signals generated in the imaging area by means of the first RF coil 14a.

Further, the image reconstruction unit 131 image-reconstructs a third reference image, based on third reference scan data as a reference scan image. That is, when the scan section 2 executes a third reference scan as a reference scan, a third reference image is image-reconstructed under a first reference scan condition similar to the above first reference scan on the basis of third reference scan data acquired by transmitting RF pulses to the imaging area by means of the first RF coil 14a and receiving magnetic resonance signals generated in the imaging area by means of the second RF coil 14b.

The transmission sensitivity distribution calculating unit 132 generates a transmission sensitivity distribution at the transmission of RF pulses by means of the RF coil unit 14 in the imaging area of the subject on the basis of the reference images and actual scan image image-reconstructed by the image reconstruction unit 131 as mentioned above.

As shown in FIG. 2, the transmission sensitivity distribution calculating unit 132 includes a division image generating part 132a, a labeling information generating part 132b, a segmentation process executing part 132c and a fitting processing part 132d. Incidentally, although the details thereof will be described later, the transmission sensitivity distribution calculating part 132 calculates a relational expression indicative of a relationship between pixel values of pixels constituting each segment in the actual scan image and their pixel positions using the fitting processing part 132d and calculates a transmission sensitivity distribution, based on the calculated relational expression.

The division image generating part 132a of the transmission sensitivity distribution calculating unit 132 executes image processing for dividing the first reference image image-reconstructed by the image reconstruction unit 131 as described above by the second reference image thereby to generate a division image.

The labeling information generating part 132b of the transmission sensitivity distribution calculating unit 132 executes labeling processing on the division image generated by the division image generating part 132a as described above thereby to generate labeling information about the division image.

The segmentation process executing part 132c of the transmission sensitivity distribution calculating unit 132 executes a segmentation process on the actual scan image, based on the labeling information generated by the labeling information generating part 132b as mentioned above thereby to extract plural segments from the actual scan image. Although the details thereof will be described later, the segmentation process executing part 132c executes image processing for dividing the actual scan image by a reception sensitivity distribution here thereby to correct the actual scan image, followed by execution of the segmentation process on the post-correction actual scan image.

The fitting processing part 132d of the transmission sensitivity distribution calculating unit 132 calculates relational expressions indicative of relationships between pixel values of pixels constituting the plural segments extracted from the actual scan image by the segmentation process executing part 132c as mentioned above and their pixel positions with respect to the segments by performing a process for fitting to polynomial models.

The reception sensitivity distribution calculating unit 133 calculates a reception sensitivity distribution at the reception of each magnetic resonance signal by the RF coil unit 14 in the imaging area of the subject. In the present embodiment, although the details thereof will be described later, the reception sensitivity distribution calculating unit 133 executes image processing for dividing a third reference image by the corresponding first reference image thereby to calculate the reception sensitivity distribution.

The image correcting unit 134 corrects the actual scan image reconstructed by the image reconstruction unit 131 using the transmission sensitivity distribution generated by the transmission sensitivity distribution calculating unit 132. Further, the image correcting unit 134 executes image processing for dividing the actual scan image by the reception sensitivity distribution thereby to correct the actual scan image.

The operation unit 32 is constituted of an operation device such as a keyboard, a pointing device or the like. The operation unit 32 inputs operation data from an operator and outputs the same to the controller 30.

The display unit 33 is constituted of a display device such as a CRT and displays each image on its display screen, based on the control signal outputted from the controller 30. For example, the display unit 33 displays images about input items corresponding to the operation data inputted to the operation unit 32 by the operator on the display screen in plural form. Further, the display unit 33 receives data about each image of the subject SU generated based on each magnetic resonance signal obtained from the subject SU from the data processor 31 and displays the image on the display screen. In the present embodiment, the display unit 33 displays the actual scan image corrected by the image correcting unit 134.

The storage unit 34 includes a memory and stores various data therein. In the storage unit 34, the stored data are accessed by the controller 30 as needed.

Operation. The operation of imaging or photographing the imaging area of the subject SU will be explained below using the magnetic resonance imaging apparatus 1 illustrative of the embodiment according to the invention.

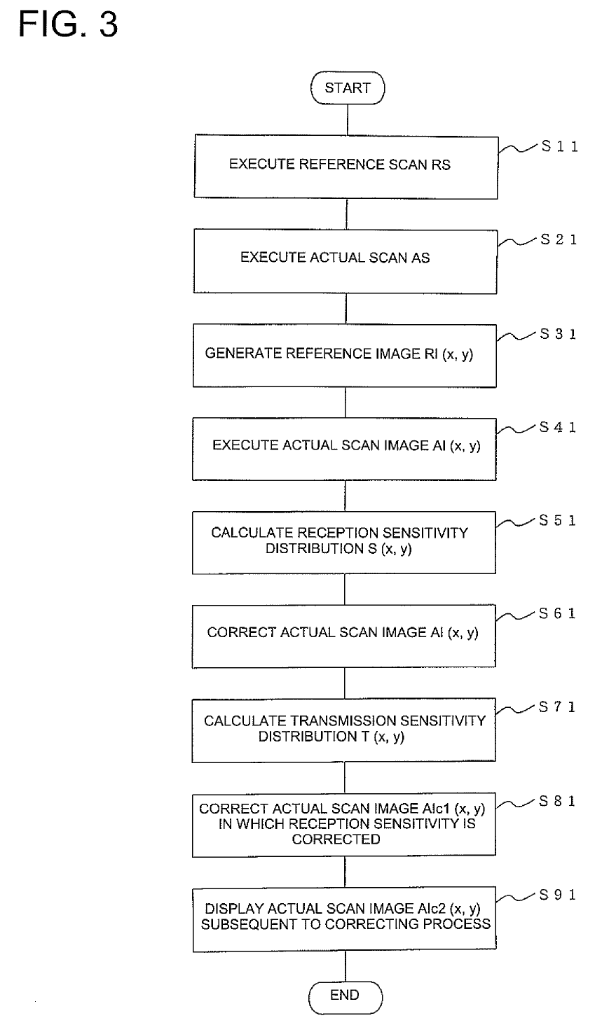

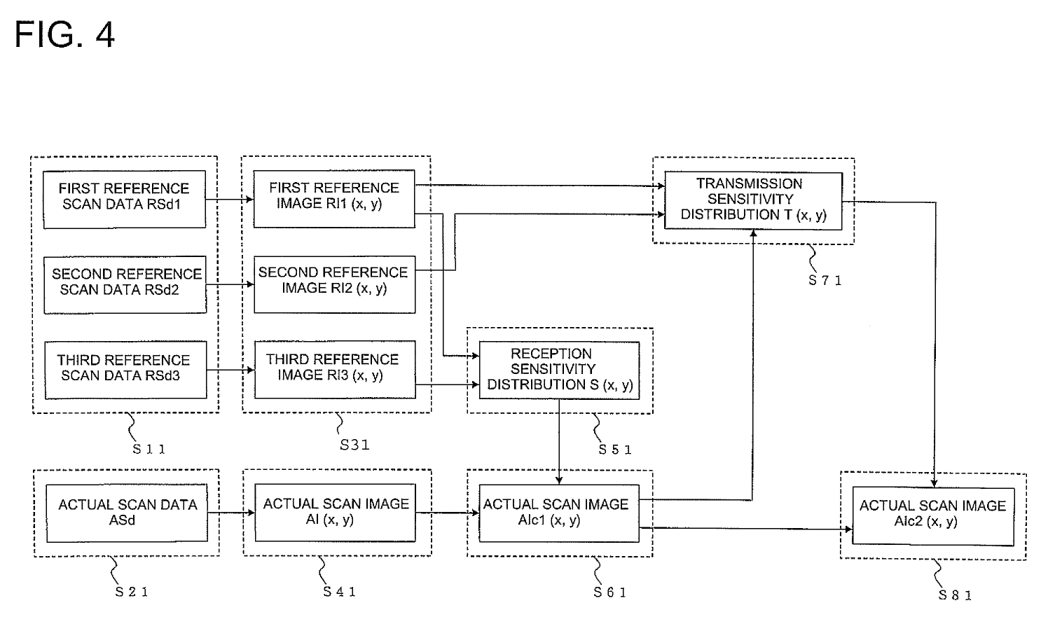

FIG. 3 is a flowchart showing the operation of imaging or photographing the imaging area of the subject SU in the embodiment according to the invention. FIG. 4 is a diagram showing the flow of data at the imaging of the imaging area of the subject SU in the embodiment according to the invention.

As shown in FIG. 3, a reference scan RS is first executed (S11).

Here, the scan section 2 executes a reference scan RS for transmitting an RF pulse to the imaging area of the subject SU imaged or photographed by an actual scan AS by using the RF coil unit 14 and receiving each magnetic resonance signal generated in the imaging area of the subject SU by using the RF coil 14.

In the present embodiment, the scan section 2 executes each of a first reference scan RS1, a second reference scan RS2 and a third reference scan RS3 as the reference scan RS. Here, the first reference scan RS1, the second reference scan RS2 and the third reference scan RS3 are respectively executed corresponding to, for example, a gradient echo pulse sequence.

Described specifically, the first reference scan RS1 is executed by a Fast SPGR method in the gradient echo pulse sequence. Here, the scan section 2 executes the first reference scan RS1 in such a manner that the first RF coil 14a corresponding to a body coil transmits an RF pulse to the imaging area of the subject SU, and the first RF coil 14a corresponding to the body coil receives a magnetic resonance signal generated in the imaging area. The magnetic resonance signal obtained by execution of the first reference scan RS1 is acquired as first reference scan data RSd1. More specifically, the first reference scan is executed under such a scan condition that, for example, TR=15 ms, TE=6 ms, FA=40° and FOV=30 cm (head) and 45 cm (abdomen), and a slice thickness of 10 mm and a matrix of 128*128 are given.

The second reference scan RS2 is different from the first reference scan RS1 and is executed by a Fast GRE method in a gradient echo pulse sequence. Here, the scan section 2 executes the second reference scan RS2 in such a manner that in a manner similar to the first reference scan RS1, the first RF coil 14a corresponding to the body coil transmits an RF pulse to the imaging area of the subject SU and the first RF coil 14a corresponding to the body coil receives a magnetic resonance signal generated in the imaging area. The magnetic resonance signal obtained by execution of the second reference scan RS2 is acquired as second reference scan data RSd2. More specifically, the second reference scan RS2 is executed under the condition that TR and TE are set identical to the first reference scan RS1 as in the case of, for example, TR=15 ms, TE=6 ms and FA=40° and the condition that RF spoiling differs from the first reference scan RS1.

The third reference scan RS3 is executed by the Fast SPGR method in the gradient echo pulse sequence in a manner similar to the first reference scan RS1. Here, as distinct from the first reference scan RS1, the scan section 2 executes the third reference scan RS3 in such a manner that the first RF coil 14a corresponding to the body coil transmits an RF pulse to the imaging area of the subject SU and the second RF coil 14b corresponding to its surface coil receives a magnetic resonance signal generated in the imaging area. The magnetic resonance signal obtained by execution of the third reference scan RS3 is acquired as third reference scan data RSd3. More specifically, the third reference scan RS3 is executed under the same condition as the first reference scan RS1 as in the case of, for example, TR=15 ms, TE=6 ms and FA=40°.

Thus, at the actual Step (S11), the first reference scan data RSd1, second reference scan data RSd2 and third reference scan data RSd3 are respectively acquired as shown in FIG. 4.

As shown in FIG. 3, the actual scan AS is next executed (S21).

Here, in the imaging space B formed with the static magnetic field, the RF coil unit 14 transmits an RF pulse to the imaging area of the subject SU and receives a magnetic resonance signal generated in the imaging area to which the RF pulse has been transmitted, as actual scan data, whereby the actual scan AS is carried out. In the present embodiment, upon execution of the actual scan AS, the first RF coil 14a transmits an RF pulse to the imaging area, and the second RF coil 14b receives a magnetic resonance signal generated in the imaging area as actual scan data ASd. More specifically, the actual scan AS is executed under a scan condition like, for example, TR=4000 ms, TE=80 ms, ETL=8, and a matrix of 256*256.

Next, as shown in FIG. 3, a reference image RI (x, y) is generated (S31).

Here, the image reconstruction unit 131 image-reconstructs a reference scan image about the imaging area of the subject SU by using each magnetic resonance signal obtained as the reference scan data by the reference scan executed on the imaging area of the subject SU in the above-described manner, as raw data.

In the present embodiment, as shown in FIG. 4, the image reconstruction unit 131 image-reconstructs a first reference image RI1 (x, y), based on the first reference scan data RSd1. That is, at the first reference scan RS1, the image reconstruction unit 131 image-reconstructs the first reference image RI1 (x, y), based on the first reference scan data RSd1 acquired by transmitting the corresponding RF pulse to the imaging area by means of the first RF coil 14a and receiving each magnetic resonance signal generated in the imaging area by means of the first RF coil 14a.

As shown in FIG. 4, the image reconstruction unit 131 image-reconstructs a second reference image RI2 (x, y), based on the second reference scan data RSd2. That is, at the second reference scan RS2, the image reconstruction unit 131 image-reconstructs the second reference image RI2 (x, y), based on the second reference scan data RSd2 acquired by transmitting the corresponding RF pulse to the imaging area by means of the first RF coil 14a and receiving each magnetic resonance signal generated in the imaging area by means of the first RF coil 14a.

As shown in FIG. 4, the image reconstruction unit 131 image-reconstructs a third reference image RI3 (x, y), based on the third reference scan data RSd3. That is, at the third reference scan RS3, the image reconstruction unit 131 image-reconstructs the third reference image RI3 (x, y), based on the third reference scan data RSd3 acquired by transmitting the corresponding RF pulse to the imaging area by means of the first RF coil 14a and receiving each magnetic resonance signal generated in the imaging area by means of the second RF coil 14b.

Next, as shown in FIG. 3, an actual scan image AI (x, y) is generated (S41).

Here, the image reconstruction unit 131 makes use of each magnetic resonance signal acquired as the actual scan data by the actual scan executed on the imaging area of the subject SU as raw data, thereby to image-reconstruct the actual scan image about the imaging area of the subject SU.

That is, as shown in FIG. 4, the actual scan image AI (x, y) is image-reconstructed based on the actual scan data ASd acquired by transmitting the corresponding RF pulse to the imaging area by means of the first RF coil 14a and receiving each magnetic resonance signal generated in the imaging area by means of the second RF coil 14b, upon execution of the actual scan.

Next, as shown in FIG. 3, a reception sensitivity distribution S (x, y) is calculated (S51).

Here, the reception sensitivity distribution calculating unit 133 calculates a reception sensitivity distribution at the reception of each magnetic resonance signal by the RF coil unit 14 in the imaging area of the subject.

In the present embodiment, as shown in FIG. 4, a reception sensitivity distribution S (x, y) is calculated using the first reference image RI1 (x, y) and the third reference image RI3 (x, y).

Described specifically, the reception sensitivity distribution calculating unit 133 executes image processing for dividing the third reference image RI3 (x, y) by the first reference image RI1 (x, y) thereby to calculate the reception sensitivity distribution S (x, y).

That is, as expressed in the following equation (1), the reception sensitivity distribution S (x, y) is calculated by executing data processing in such a manner that the reception sensitivity distribution calculating unit 133 divides pixel data at respective pixels (x, y) of the third reference image RI3 (x, y) by pixel data at respective pixels (x, y) of the first reference image RI1 (x, y).

$$S ( x , y ) = \frac{RI 3 ( x , y )}{RI 1 ( x , y )} \qquad ( 1 )$$

Next, as shown in FIG. 3, the actual scan image AI (x, y) is corrected (S61).

Here, the image correcting unit 134 corrects the actual scan image AI (x, y).

In the present embodiment, as shown in FIG. 4, the actual scan image AI (x, y) is corrected using the reception sensitivity distribution S (x, y).

Described specifically, as expressed in the following equation (2), a post-correction actual scan image AIc1 (x, y) is determined by executing data processing in such a manner that pixel data at respective pixels (x, y) of the actual scan image AI (x, y) are respectively divided by pixel data at respective pixels (x, y) of the reception sensitivity distribution S (x, y).

$$AIc 1 ( x , y ) = \frac{AI ( x , y )}{S ( x , y )} \qquad ( 2 )$$

Next, a transmission sensitivity distribution T (x, y) is calculated (S71).

Here, the transmission sensitivity distribution calculating unit 132 calculates a transmission sensitivity distribution at the transmission of each RF pulse by the RF coil unit 14 in the imaging area of the subject.

In the present embodiment, as shown in FIG. 4, the transmission sensitivity distribution T (x, y) is generated based on the first reference image RI1 (x, y) and second reference image RI2 (x, y) reconstructed as the reference images, and the actual scan image AIc1 (x, y) corrected for the reception sensitivity.

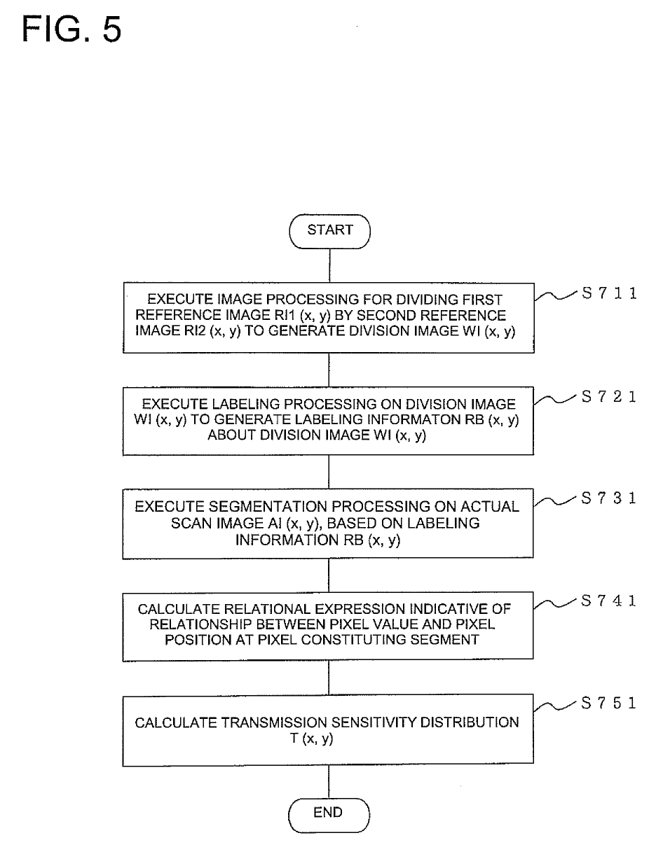

FIG. 5 is a flowchart showing operation taken when the transmission sensitivity distribution T (x, y) is generated in the embodiment according to the invention.

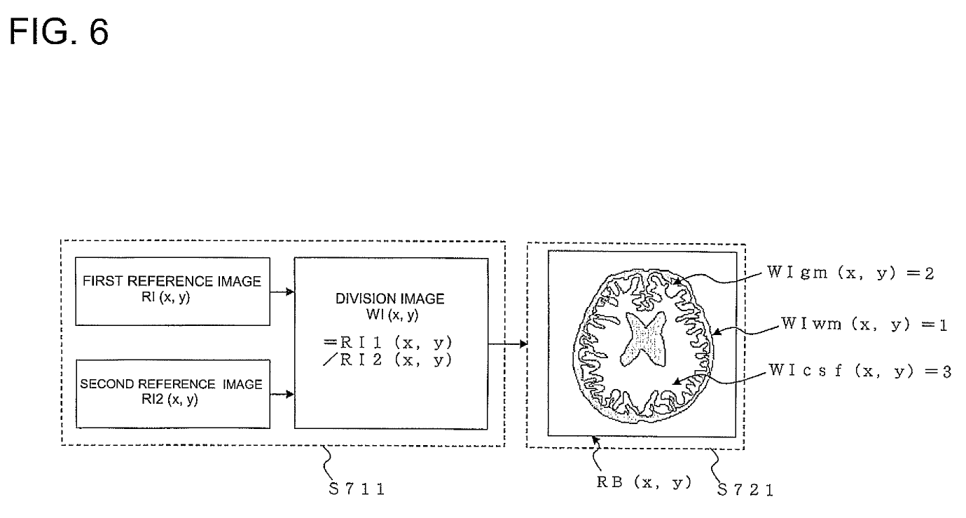

FIGS. 6, 7 and 8 are respectively diagrams for conceptually describing operation taken when the transmission sensitivity distribution T (x, y) is generated in the embodiment according to the invention.

Upon generating the transmission sensitivity distribution T (x, y), as shown in FIG. 5, image processing for dividing the first reference image RI1 (x, y) by the corresponding second reference image RI2 (x, y) is first executed, thereby generating a division image WI (x, y) (S711).

Here, the division image generating part 132a of the transmission sensitivity distribution calculating unit 132 generates the division image WI (x, y).

Described specifically, the division image generating part 132a of the transmission sensitivity distribution calculating unit 132 receives image data about the first reference image RI1 (x, y) and second reference image RI2 (x, y) image-reconstructed by the image reconstruction unit 131 as described above. Thereafter, as expressed in the following equation (3), the division image WI (x, y) is generated as shown in FIG. 6 by executing data processing for dividing pixel data at respective pixels (x, y) of the first reference image RI1 (x, y) by pixel data at respective pixels (x, y) of the second reference image RI2 (x, y). The division image WI (x, y) is generated as an image from which transmission sensitivity nonuniformity is removed and which indicates contrast that depends on each tissue in the imaging area.

$$WI ( x , y ) = \frac{RI 1 ( x , y )}{RI 2 ( x , y )} \qquad ( 3 )$$

Next, as shown in FIG. 5, a labeling process is performed on the division image WI (x, y) to generate labeling information RB (x, y) about the division image WI (x, y).

Here, the labeling information generating part 132b of the transmission sensitivity distribution calculating unit 132 generates the labeling information RB (x, y) about the division image WI (x, y) (S721).

Described specifically, the labeling information generating part 132b receives pixel data of the division image WI (x, y) generated by the division image generating part 132a as described above. Thereafter, pixel data at respective pixels (x, y) of the division image WI (x, y) are sorted by executing threshold processing, based on a preset threshold value, and a labeling process is executed in such a manner that labels different according to the sorting of the pixel data are affixed.

As shown in FIG. 6, for example, the threshold processing is performed on the pixel data at the respective pixels (x, y) of the division image WI (x, y), thereby bringing to segmentation so as to assume respective segments of a pixel area WIwm (x,y) corresponding to cerebral fluid, a pixel area WIgm (x, y) corresponding to cerebral gray matter and a pixel area WIcsf (x, y) corresponding to cerebral while matter.

That is, when the pixel data at the respective pixels (x, y) of the division image WI (x, y) correspond to a threshold range corresponding to the cerebral fluid, they are subjected to segmentation as the pixel area WIwm (x, y) corresponding to the cerebral fluid. For instance, each pixel having a signal intensity of 5.0 or more is sorted as the pixel area WIgm (x, y) corresponding to the cerebral fluid. Similarly, when the pixel data at the respective pixels (x, y) of the division image WI (x, y) correspond to a threshold range corresponding to the cerebral gray matter, they are brought into segmentation as the pixel area WIgm (x, y) corresponding to the cerebral gray matter. For example, each pixel at which the signal intensity exceeds 3.0 and is less than 5.0 is sorted as the pixel area WIwm (x, y) corresponding to the cerebral gray matter. Similarly, when the pixel data at the respective pixels (x, y) of the division image WI (x, y) correspond to a threshold range corresponding to the cerebral white matter, they are brought into segmentation as the pixel area WIcsf (x, y) corresponding to the cerebral white matter. For example, each pixel at which its signal intensity is 3.0 or less, is sorted as the pixel area WIcsf (x, y) corresponding to the cerebral white matter.

At the respective segments brought into segmentation as described above, for example, a label of a numeral “1” is affixed to the pixel area WIwm (x, y) corresponding to the cerebral fluid as expressed in the following equation (4). As expressed in the following equation (5), for example, a label of “2” is affixed to the pixel area WIgm (x, y) corresponding to the cerebral gray matter. As expressed in the following equation (6), a label of “3” is affixed to the pixel area WIcsf (x, y) corresponding to the cerebral white matter. That is, they are sorted so as to correspond to respective tissues contained in the imaging area in plural form, and integers are given to the respective pixels according to the sorting thereof, thereby setting them as labels, whereby they are stored as image information.

WIwm(x,y)=1 (4)

WIgm(x,y)=2 (5)

WIcsf(x,y)=3 (6)

Thus, the labeling process is executed on the division image WI (x, y) to generate labeling information RB (x, y) about the pixel area WIwm (x, y) corresponding to the cerebral fluid, the pixel area WIgm (x, y) corresponding to the cerebral white matter and the pixel area WIcsf (x, y) corresponding to the cerebral white matter. A distribution of plural tissues existing in the imaging area is estimated in the labeling information RB (x, y).

Next, as shown in FIG. 5, a segmentation process is executed on the actual scan image AI (x, y), based on the labeling information RB (x, y)(S731).

Here, the segmentation process executing part 132c of the transmission sensitivity distribution calculating unit 132 executes the segmentation process.

In the present embodiment, the segmentation process is performed on the post-correction actual scan image AIc1 corrected for reception sensitivity, based on the labeling information RB (x, y) generated in the above-described manner, and plural segments are extracted from the post-correction actual scan image AIc1 (x, y).

Described specifically, the segmentation process executing part 132c receives image data of the post-correction actual scan image AIc1 (x, y) and data of the labeling information RB (x, y). Thereafter, the pixel data at the respective pixels (x, y) of the post-correction actual scan image AIc1 (x, y) are brought into segmentation so as to assume segments corresponding to labels, based on pixel positions where the labels are affixed with respect to the labeling information RB (x, y).

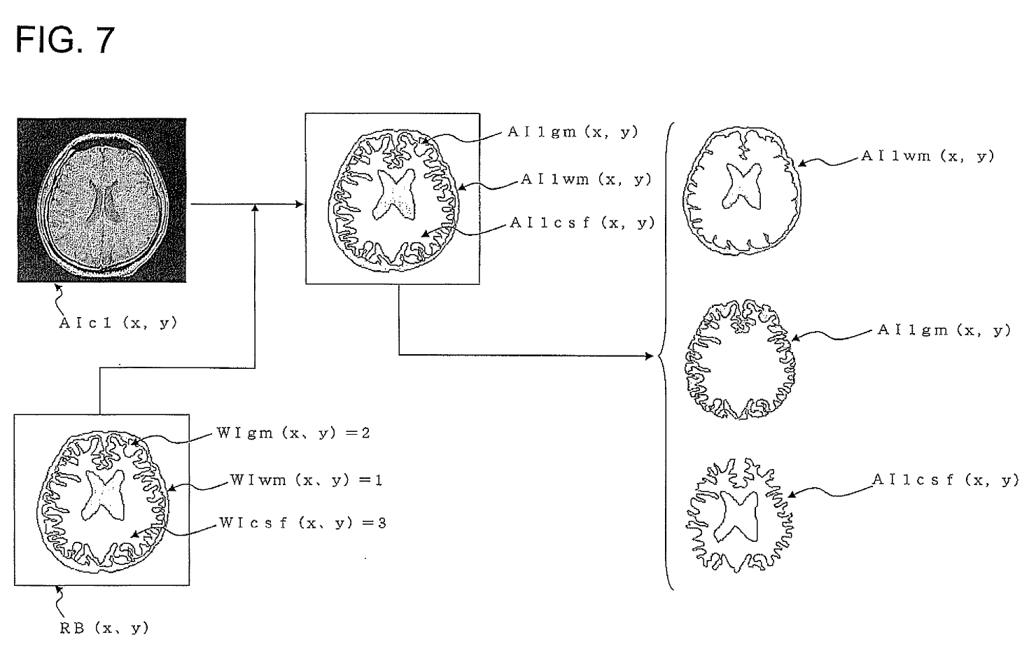

That is, as shown in FIG. 7, an area corresponding to the pixel area WIwm (x, y) marked with the label of “1” at the labeling information RB (x, y) is brought into segmentation as a pixel area AI1wm (x, y) corresponding to the cerebral fluid at the post-correction actual scan image AIc1 (x, y). Likewise, an area corresponding to the pixel area WIgm (x, y) marked with the label of “2” at the labeling information RB (x, y) is brought into segmentation as a pixel area AI1gm (x, y) corresponding to the cerebral gray matter at the post-correction actual scan image AIc1 (x, y). An area corresponding to the pixel area WIcsf (x, y) marked with the label of “3” at the labeling information RB (x, y) is brought into segmentation as a pixel area AI1csf (x, y) corresponding to the cerebral gray matter at the post-correction actual scan image AIc1 (x, y).

Incidentally, when each pixel of the actual scan image AIc1 (x, y) for diagnosis and each pixel of the labeling information RB (x, y) do not coincide in position here, an interpolation process is carried out in such a manner that the first, second and third reference images are respectively brought to the same position and resolution as the actual scan image, and segmentation and label processing are executed, whereby they are sorted so as to assume segments at the same positions.

Next, as shown in FIG. 5, a relational expression indicative of a relationship between pixel values of pixels constituting each segment and pixel positions thereof is calculated (S741).

Here, the fitting processing part 132d of the transmission sensitivity distribution calculating unit 132 calculates each relational expression.

In the present embodiment, the relational expressions indicative of the relationship between the pixel values of pixels constituting the plural segments extracted as the pixel area AI1wm (x, y) corresponding to the cerebral fluid, the pixel area AI1gm (x, y) corresponding to the cerebral gray matter, and the pixel area AI1csf (x, y) corresponding to the cerebral gray matter as described above are calculated with respect to the plural segments by performing a process for fitting to polynomial models.

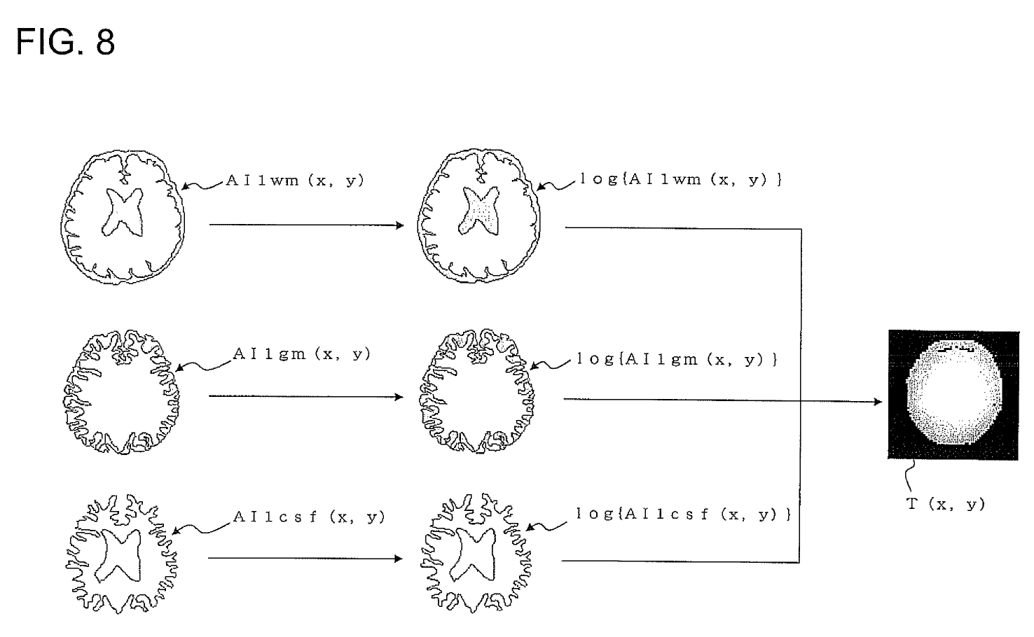

Here, as shown in FIG. 8, pixel data of pixel data AI1wm (x, y) of the pixel area corresponding to the cerebral fluid, pixel data AI1gm (x, y) of the pixel area corresponding to the cerebral gray matter and pixel data AI1csf (x, y) of the pixel area corresponding to the cerebral gray matter are respectively log-transformed. Thereafter, data log{AI1wm (x, y)}, log{AI1gm (x, y)} and log{AI1csf (x, y)} log-transformed with respect to the pixel areas AI1wm (x, y), AI1gm (x, y) and AI1csf (x, y) are subjected to a fitting process for secondary polynomial models as expressed in the following equations (7), (8) and (9). Incidentally, higher-order models may be used as the polynomial models. Alternatively, an orthogonal polynomial system may be used.

log{AI1wm(x,y)}=a1·x²+a2·y²+a3·xy+a4·x+a5·y+Cwm (7)

log{AI1gm(x,y)}=a1·x²+a2·y²+a3·xy+a4·x+a5·y+Cgm (8)

log{AI1csf(x,y)}=a1·x²+a2·y²+a3·xy+a4·x+a5·y+Ccsf (9)

Next, as shown in FIG. 5, a transmission sensitivity distribution T (x, y) is calculated (S751).

Here, the transmission sensitivity distribution calculating unit 132 generates the transmission sensitivity distribution T (x, y), based on the relational expressions calculated like the above equations (7), (8) and (9).

In the present embodiment, a relational expression given as the following equation (10) is derived from the relational expressions calculated like the equations (7), (8) and (9). Here, this relational expression is derived by extracting a sensitivity ununiform component common to the respective tissues. That is, the common sensitivity ununiform component is extracted by deriving constant terms of the equations (7), (8) and (9).

log{T(x,y)}=a1·x²+a2·y²+a3·xy+a4·x+a5·y (10)

The relational expression of the equation (10) is exponentially transformed to calculate the transmission sensitivity distribution T (x, y) from a relational expression expressed in the following equation (11).

T(x,y)=exp(a1·x²+a2·y²+a3·xy+a4·x+a5·y) (11)

The transmission sensitivity distribution T (x, y) is calculated in this way.

Next, as shown in FIG. 3, the actual scan image AIc1 (x, y) corrected for reception sensitivity is corrected (S81).

Here, the image correcting unit 134 corrects the actual scan image AIc1 (x, y) corrected for the reception sensitivity, using the transmission sensitivity distribution T (x, y) generated by the transmission sensitivity distribution calculating unit 132 as described above.

Described specifically, data processing is carried out in such a manner that the pixel data at the respective pixels (x, y) of the actual scan image AIc1 (x, y) corrected for the reception sensitivity are divided by their corresponding data at respective pixels (x, y) of the transmission sensitivity distribution T (x, y) as expressed in the following equation (12), thereby generating a post-correction actual scan image AIc2 (x, y) at which transmission sensitivity has been corrected.

$$AIc 2 ( x , y ) = \frac{AIc 1 ( x , y )}{T ( x , y )} \qquad ( 12 )$$

Next, as shown in FIG. 3, the display of the actual scan image AIc2 (x, y) subsequent to the correcting process is executed (S91).

Here, the display unit 33 displays the actual scan image AIc2 (x, y) corrected by the image correcting unit 134 as described above.

In the present embodiment as described above, the plural segments are extracted from the actual scan image AI1c (x, y) using the labeling information RB (x, y) indicative of the respective tissues at the division image WI (x, y) from which the transmission sensitivity non-uniformity is removed, and indicative of contrast depending on only the tissues in the imaging area. The relational expressions indicative of the relationships between the pixel values of the pixels constituting the respective segments extracted from the actual scan image AI1c (x, y) and their pixel positions are calculated with respect to the segments by performing the process for fitting to the polynomial models. The transmission sensitivity distribution T (x, y) is generated based on the calculated relational expressions. The correction for the actual scan image AI1c (x, y) is executed using the so-calculated transmission sensitivity distribution T (x, y). Thus, the present embodiment can carry out a sensitivity correction while maintaining the contrast between the tissues to use the prior information of the tissue distribution. Since the transmission sensitivity distribution T (x, y) is calculated from the actual scan image AI1c (x, y) targeted for correction, a sensitivity correction can effectively be effected on the sensitivity non-uniformity that depends on each sequence parameter. Since the prior information of the tissue distribution is obtained in advance, the present embodiment is capable of simplifying an algorithm for calculating the transmission sensitivity distribution T (x, y). Therefore, the transmission sensitivity distribution T (x, y) can be calculated at high speed.

Accordingly, the present embodiment is capable of measuring a transmission sensitivity distribution with a high degree of accuracy and improving image quality.

Incidentally, in the above embodiment, the magnetic resonance imaging apparatus 1 corresponds to the MRI apparatus of the invention. In the above embodiment, the scan section 2 corresponds to the scanner or scan section of the invention. In the above embodiment, the operation console section 3 corresponds to the sensitivity distribution measuring apparatus of the invention. In the above embodiment, the RF coil unit 14 corresponds to the RF coil part of the invention. In the above embodiment, the first RF coil 14a corresponds to the first RF coil of the invention. In the above embodiment, the second RF coil 14b corresponds to the second RF coil of the invention. The display unit 33 of the above embodiment corresponds to the display or displayer of the invention. The image reconstruction unit 131 of the above embodiment corresponds to the image reconstructer of the invention. The transmission sensitivity distribution calculating unit 132 of the above embodiment corresponds to the transmission sensitivity distribution calculator of the invention. In the above embodiment, the division image generating part 132a corresponds to the division image generator of the invention. In the above embodiment, the labeling information generating part 132b corresponds to the labeling information generator of the invention. In the above embodiment, the segmentation process executing part 132c corresponds to the segmentation process executer of the invention. In the above embodiment, the fitting processing part 132d corresponds to the fitting processor of the invention. In the above embodiment, the reception sensitivity distribution calculating unit 133 corresponds to the reception sensitivity distribution calculator of the invention. The image correcting unit 134 of the above embodiment corresponds to the image collector of the invention. The imaging space B of the above embodiment corresponds to the static magnetic field space of the invention.

Upon implementation of the invention, the invention is not limited to the above embodiment. Various modifications can be adopted.

Although the above embodiment has explained the case in which the scan is executed in the gradient echo pulse sequence, for example, the invention may be applied to the case in which the scan is executed in a spin echo pulse sequence. In this case, for example, the first reference scan RS1 and the third reference scan RS3 are executed in such a manner that a proton-emphasized image is generated by a Fast SE method. The second reference scan RS2 is executed in such a manner that a T2-emphasized image is generated by the Fast SE method.

Many widely different embodiments of the invention may be configured without departing from the spirit and the scope of the present invention. It should be understood that the present invention is not limited to the specific embodiments described in the specification, except as defined in the appended claims.

1. A magnetic resonance imaging apparatus configured to execute a scan in which an RF coil unit transmits RF pulses to an imaging area of a subject in a static magnetic field space and acquires magnetic resonance signals generated in the imaging area, said apparatus comprising:
a scan section configured to execute the scan, the scan including an actual scan for acquiring the magnetic resonance signals as actual scan data and a reference scan for acquiring the magnetic resonance signals as reference scan data;
an image reconstruction unit configured to reconstruct an actual scan image about the imaging area, area based on the actual scan data and configured to reconstruct a reference scan image about the imaging; area based on the reference scan data;
a transmission sensitivity distribution calculating unit configured to calculate a transmission sensitivity distribution at the transmission of the RF pulses by the RF coil unit, the transmission sensitivity distribution calculated based on the reference scan image and the actual scan image; and
an image correcting unit configured to correct the actual scan image using the transmission sensitivity distribution,
wherein the RF coil unit includes a first RF, coil having a uniform reception sensitivity distribution and a second RF coil having a non-uniform in reception sensitivity distribution,
wherein of during, the actual scan, the scan section is configured to transmit the RF pulses to the imaging area by the first RF coil and is configured to receive the magnetic resonance signals generated in the imaging area as the actual scan data by the second RF coil, and
wherein during the reference scan, the scan section is configured to execute:
a first reference scan in which RF pulses are transmitted to the imaging area by the first RF coil and magnetic resonance signals generated in the imaging area as first reference scan data are received by the first RF coil under a first reference scan condition corresponding to a pulse sequence of one of a spin echo system and a gradient echo system, and
a second reference scan in which RF pulses are transmitted to the imaging area by the first RF coil and magnetic resonance signals generated in the imaging area as second reference scan data are received by the first RF coil under a second reference scan condition corresponding to the same pulse sequence as the first reference scan condition and different from the first reference scan condition in terms of at least one other scan parameter,
wherein the image reconstruction unit is configured to image-reconstruct a first reference image as the reference scan based on the first reference scan data and is configured to image-reconstruct a second reference image as the reference scan image, based on the second reference scan data,
wherein the transmission sensitivity distribution calculating unit comprises:
a division image generating part configured to execute image processing for dividing the first reference image by the second reference image thereby generating a division image;
a labeling information generating part configured to execute a labeling process on the division image to generate labeling information about the division image;
a segmentation process executing part configured to execute a segmentation process on the actual scan image based on the labeling information to extract a plurality of segments from the actual scan image; and
a fitting processing part configured to calculate relational expressions indicative of relationships between pixel values of pixels constituting the segments and pixel positions thereof with respect to the segments extracted from the actual scan image by performing a process for fitting to polynomial models, and
wherein the transmission sensitivity distribution is calculated based on the relational expressions calculated by the fitting processing part.

2. The magnetic resonance imaging apparatus according to claim 1, further comprising a reception sensitivity distribution calculating unit configured to calculate a reception sensitivity distribution at the reception of the magnetic resonance signals by the RF coil unit in the imaging area,
wherein the image correcting unit is configured to execute image processing for dividing the actual scan image by the reception sensitivity distribution to correct the actual scan image.

3. The magnetic resonance imaging apparatus according to claim 2, wherein the segmentation process executing part is configured to execute image processing for dividing the actual scan image by the reception sensitivity distribution thereby to correct the actual scan image and is further configured to execute the segmentation process on the post-correction actual scan image.

4. The magnetic resonance imaging apparatus according to claim 2,
wherein the scan section is configured to execute, as the reference scan, a third reference scan in which RF pulses are transmitted to the imaging area by the first RF coil and magnetic resonance signals generated in the imaging area as third reference scan data are received by the second RF, coil under the first reference scan condition,
wherein the image reconstruction unit is configured to image-reconstruct a third reference image as the reference scan, image based on the third reference scan data, and
wherein the reception sensitivity distribution calculating unit is configured to execute image processing for dividing the third reference image by the first reference image to calculate the reception sensitivity distribution.

5. The magnetic resonance imaging apparatus according to claim 3,
wherein the scan section is configured to execute, as the reference scan, a third reference scan in which RF pulses are transmitted to the imaging area by the first RF coil and magnetic resonance signals generated in the imaging area as third reference scan data are received by the second RF, coil under the first reference scan condition,
wherein the image reconstruction unit is configured to image-reconstruct a third reference image as the reference scan, image based on the third reference scan data, and
wherein the reception sensitivity distribution calculating unit executes is configured to execute image processing for dividing the third reference image by the first reference image to calculate the reception sensitivity distribution.

6. The magnetic resonance imaging apparatus according to claim 1,
wherein the first RF coil is a body coil and the second RF coil is a surface coil.

7. The magnetic resonance imaging apparatus according to claim 2,
wherein the first RF coil is a body coil and the second RF coil is a surface coil.

8. The magnetic resonance imaging apparatus according to claim 3, wherein the first RF coil is a body coil and the second RF coil is a surface coil.

9. The magnetic resonance imaging apparatus according to claim 4, wherein the first RF coil is a body coil and the second RF coil is a surface coil.

10. The magnetic resonance imaging apparatus according to claim 1, further comprising a display unit configured to display the actual scan image corrected by the image correcting unit.

11. A magnetic resonance imaging method which executes a scan for causing an RF coil unit including a first RF coil having a uniform reception sensitivity distribution and a second RF coil having a non-uniform reception sensitivity distribution coil to transmit RF pulses to an imaging area of a subject in a static magnetic field space, and in which the RF coil unit acquires magnetic resonance signals generated in the imaging area, thereby generating images about the imaging area, said method comprising:
executing, as the scan, each of an actual scan for acquiring the magnetic resonance signals as actual scan data and a reference scan for acquiring the magnetic resonance signals as reference scan data;
reconstructing an actual scan image about the imaging area based on the actual scan data and reconstructing a reference scan image about the imaging area based on the reference scan data;
calculating a transmission sensitivity distribution at the transmission of the RF pulses by the RF coil unit in the imaging area based on the reference scan image and the actual scan image; and
correcting the actual scan image using the transmission sensitivity distribution,
wherein, when the actual scan is executed, the first RF coil transmits RF pulses to the imaging area and the second RF coil receives magnetic resonance signals generated in the imaging area as the actual scan data, whereas when the reference scan is executed, a first reference scan is executed in which RF pulses are transmitted to the imaging area by the first RF coil and magnetic resonance signals generated in the imaging area as first reference scan data are received by the first RF coil under a first reference scan condition corresponding to a pulse sequence of a spin echo system or a gradient echo system, and a second reference scan is executed in which RF pulses are transmitted to the imaging area by the first RF coil and magnetic resonance signals generated in the imaging area as second reference scan data are received by the first RF coil under a second reference scan condition corresponding to the same pulse sequence as the first reference scan condition and different from the first reference scan condition in terms of at least one of other scan parameters are executed,
wherein reconstructing an actual scan image and a reference scan image comprises image-reconstructing a first reference image as the reference scan image, image based on the first reference scan data, and image-reconstructing a second reference image as the reference scan image based on the second reference scan data,
wherein calculating the transmission sensitivity distribution comprises:
executing image processing for dividing the first reference image by the second reference image to generate a division image;
executing a labeling process on the division image to generate labeling information about the division image;
executing a segmentation process on the actual scan image based on the labeling information to extract a plurality of segments from the actual scan image; and
calculating relational expressions indicative of relationships between pixel values of pixels constituting the segments and pixel positions thereof with respect to the segments extracted from the actual scan image by performing a process for fitting to polynomial models, and
wherein the transmission sensitivity distribution is calculated based on the relational expressions calculated by the process for fitting.

12. The magnetic resonance imaging method according to claim 11, further comprising calculating a reception sensitivity distribution at the reception of the magnetic resonance signals by the RF coil unit in the imaging area,
wherein image processing for dividing the actual scan image by the reception sensitivity distribution is executed to correct the actual scan image.

13. The magnetic resonance imaging method according to claim 12, wherein executing a segmentation process comprises executing, image processing for dividing the actual scan image by the reception sensitivity distribution is to correct the actual scan image and thereafter, the segmentation process is performed on the post-correction actual scan image.

14. The magnetic resonance imaging method according to claim 12,
wherein executing an actual scan and a reference scan comprises executing a third reference scan in which RF pulses are transmitted to the imaging area by the first RF coil and magnetic resonance signals generated in the imaging area are received by the second RF coil as third reference scan data, under the first reference scan condition,
wherein reconstructing an actual scan image and a reference scan image comprises reconstructing a third reference image as the reference scan image based on the third reference scan data, and
wherein calculating a reception sensitivity distribution comprises executing image processing for dividing the third reference image by the first reference image is executed to calculate the reception sensitivity distribution.

15. The magnetic resonance imaging method according to claim 11, wherein the first RF coil is a body coil and the second RF coil is a surface coil.

16. The magnetic resonance imaging method according to claim 11, further comprising displaying the corrected actual scan image.

17. A sensitivity distribution measuring apparatus configured to execute a scan in which an RF coil unit transmits RF pulses to an imaging area of a subject in a static magnetic field space and acquires magnetic resonance signals generated in the imaging area, the scan including an actual scan for acquiring the magnetic resonance signals as actual scan data and a reference scan for acquiring the magnetic resonance signals as reference scan data, said sensitivity distribution measuring apparatus further configured to calculate a transmission sensitivity distribution at the transmission of the RF pulses by the RF coil unit in the imaging area based on the actual scan data and the reference scan data, said sensitivity distribution measuring apparatus comprising:
an image reconstruction unit configured to reconstruct an actual scan image about the imaging area based on the actual scan data and configured to reconstruct a reference scan image about the imaging area based on the reference scan data; and
a transmission sensitivity distribution calculating unit configured to calculate a transmission sensitivity distribution at the transmission of the RF pulses by the RF coil unit in the imaging area, the transmission sensitivity distribution based on the reference scan image and the actual scan image,
wherein the RF coil unit includes a first RF coil having a uniform reception sensitivity distribution in the imaging area and a second RF coil having a non-uniform reception sensitivity distribution in the imaging area,
wherein during the actual scan, the first RF coil is configured to transmit the RF pulses to the imaging area, and the second RF coil is configured to receive the magnetic resonance signals generated in the imaging area as the actual scan data,
wherein during the reference scan, the first RF coil is configured to execute a first reference scan by transmitting RF pulses to the imaging area and receiving magnetic resonance signals generated in the imaging area as first reference scan data, under a first reference scan condition corresponding to a pulse sequence of one of a spin echo system and a gradient echo system, the first RF coil is further configured to execute a second reference scan by transmitting RF pulses to the imaging area and receiving magnetic resonance signals generated in the imaging area as second reference scan data under a second reference scan condition corresponding to the same pulse sequence as the first reference scan condition and different from the first reference scan condition in terms of at least one other scan parameter are executed,
wherein when the reference scan image is reconstructed, a first reference image is image-reconstructed based on the first reference scan data and a second reference image is image-reconstructed based on the second reference scan data,
wherein the image reconstruction unit is configured to image-reconstruct the first reference image as the reference scan image based on the first reference scan data, and is further configured to image-reconstruct the second reference image as the reference scan image based on the second reference scan data,
wherein the transmission sensitivity distribution calculating unit includes:
a division image generating part configured to execute image processing for dividing the first reference image by the second reference image thereby generating a division image;
a labeling information generating part configured to execute a labeling process on the division image to generate labeling information about the division image;
a segmentation process executing part configured to execute a segmentation process on the actual scan image based on the labeling information to extract a plurality of segments from the actual scan image; and
a fitting processing part configured to calculate relational expressions indicative of relationships between pixel values of pixels constituting the segments and pixel positions thereof with respect to the segments extracted from the actual scan image by performing a process for fitting to polynomial models, and
wherein the transmission sensitivity distribution is calculated based on the relational expressions calculated by the fitting processing part.

18. The sensitivity distribution measuring apparatus according to claim 17, further comprising a reception sensitivity distribution calculating unit configured to calculate a reception sensitivity distribution at the reception of the magnetic resonance signals by the RF coil unit in the imaging area,
wherein the segmentation process executing part is configured to execute image processing for dividing the actual scan image by the reception sensitivity distribution to correct the actual scan image and thereafter executes the segmentation process on the post-correction actual scan image.

19. The sensitivity distribution measuring apparatus according to claim 18,
wherein the scan section is configured to execute, as the reference scan, a third reference scan for transmitting RF pulses to the imaging area by the first RF coil and receiving magnetic resonance signals generated in the imaging area as third reference scan data by the second RF coil,
wherein the image reconstruction unit is configured to image-reconstruct a third reference image as the reference scan image based on the third reference scan data, and
wherein the reception sensitivity distribution calculating unit is configured to execute image processing for dividing the third reference image by the first reference image to calculate the reception sensitivity distribution.

20. The sensitivity distribution measuring apparatus according to claim 17, wherein the first RF coil is a body coil and the second RF coil is a surface coil.
